(19) United States
(12) Patent Application Publication
(10) Pub. No.: US 2020/0019059 A1
(43) Pub. Date: Jan. 16, 2020

(54) NEGATIVE PHOTOSENSITIVE RESIN COMPOSITION

(71) Applicant: ZEON CORPORATION, Chiyoda-ku Tokyo (JP)

(72) Inventor: Takaaki SAKURAI, Chiyoda-ku, Tokyo (JP)

(73) Assignee: ZEON CORPORATION, Chiyoda-ku Tokyo (JP)

(21) Appl. No.: 16/483,509

(22) PCT Filed: Jan. 17, 2018
(86) PCT No.: PCT/JP2018/001272

§ 371 Date: Aug. 5, 2019

(30) Foreign Application Priority Data
Feb. 21, 2017 (JP) 2017-030434

(51) Int. Cl. G03F 7/038; G03F 7/004; C08K 5/1515; C08F 32/00; C08K 5/06; C08K 5/544

(52) U.S. Cl. CPC G03F 7/0382; G03F 7/0045; C08K 5/544; C08F 32/00; C08K 5/06; C08K 5/1515

(57) ABSTRACT

A negative photosensitive resin composition contains an alkali-soluble resin, a non-ionic photoacid generator, and a sensitizer.

### TECHNICAL FIELD

The present disclosure relates to a negative photosensitive resin composition.

### BACKGROUND

In recent years, various resin films have been used in electronic components such as integrated circuit elements and organic EL elements. Examples of such resin films include protective films for preventing degradation and damage of components themselves, planarizing films for flattening element surfaces and wiring, electrical insulation films for ensuring electrical insulation, pixel separation films for separating light-emitting parts, and optical films for focusing and diffusing light.

Photosensitive resin compositions having high photoexposure sensitivity have been proposed as photosensitive resin compositions capable of forming resin films that can be used in the various applications described above (for example, refer to Patent Literature (PTL) 1). A photosensitive resin composition described in PTL 1 contains an acidic group-containing alicyclic olefin polymer as an alkali-soluble resin, a sulfonium salt-based photoacid generator having a certain structure as an ionic photoacid generator, and a crosslinking agent. This photosensitive resin composition enables formation of a resin film having high photoexposure sensitivity and also enables production of a resin film having a desired pattern with a high production yield.

### CITATION LIST

### Patent Literature

PTL 1: WO 2015/033901 A1

### SUMMARY

### Technical Problem

A photosensitive resin composition is not necessarily used straight after production and may actually be used in formation of a resin film after a certain storage period or distribution stage. Although the photosensitive resin composition described in PTL 1 can be used to form a resin film having high sensitivity, there is room for improvement of the composition in terms of storage stability.

Accordingly, an objective of the present disclosure is to provide a photosensitive resin composition that has excellent storage stability and can form a resin film having sufficiently high sensitivity.

### Solution to Problem

The inventor conducted diligent investigation with the aim of solving the problem set forth above. During this investigation, the inventor conceived an idea of using a non-ionic photoacid generator as a photoacid generator in a photosensitive resin composition. As a result of further investigation carried out based on this idea, the inventor made a new discovery that by using a non-ionic photoacid generator and a sensitizer in combination in a photosensitive resin composition, it is possible to provide a photosensitive resin composition that has excellent storage stability and can sufficiently increase the sensitivity of a resin film obtained therewith. In this manner, the inventor completed the present disclosure.

Specifically, the present disclosure aims to advantageously solve the problem set forth above by disclosing a negative photosensitive resin composition comprising an alkali-soluble resin, a non-ionic photoacid generator, and a sensitizer. The presently disclosed negative photosensitive resin composition has excellent storage stability and can be used to form a resin film having sufficiently high sensitivity to light.

The term “alkali-soluble resin” as used in the present description refers to a resin that is soluble in a developer used in development of a negative photosensitive resin composition containing the resin as a component, and particularly preferably in an alkaline developer.

In the presently disclosed negative photosensitive resin composition, the non-ionic photoacid generator is preferably a compound represented by general formula (I), shown below,

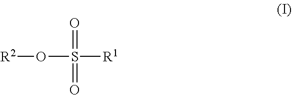

where, in general formula (I), R¹ indicates an optionally substituted alkyl group having a carbon number of 4 or less or an optionally substituted phenyl group, and R² indicates a nitrogen atom-containing organic group. When the non-ionic photoacid generator is a compound that can be represented by formula (I), storage stability of the negative photosensitive resin composition can be further improved, and sensitivity of an obtained resin film can be further increased.

Moreover, in the presently disclosed negative photosensitive resin composition, R¹ is preferably a trifluoromethyl group. A resin film obtained using a negative photosensitive resin composition containing a photoacid generator that is represented by formula (I) and for which R¹ is a trifluoromethyl group has even higher sensitivity.

Furthermore, in the presently disclosed negative photosensitive resin composition, R² is preferably a naphthalimide group. A resin film obtained using a negative photosensitive resin composition containing a photoacid generator that is represented by formula (I) and for which R² is a naphthalimide group has even higher sensitivity.

In the presently disclosed negative photosensitive resin composition, the sensitizer is preferably a compound represented by general formula (II), shown below,

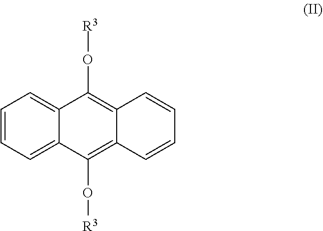

where, in general formula (II), R³ indicates an optionally substituted alkyl group having a carbon number of 6 or less. A resin film obtained using a negative photosensitive resin composition containing a sensitizer satisfying formula (II) has even higher sensitivity.

Moreover, in the presently disclosed negative photosensitive resin composition, R³ is preferably an unsubstituted alkyl group having a carbon number of 6 or less. A resin film obtained using a negative photosensitive resin composition containing a sensitizer that satisfies formula (II) and for which R³ is an unsubstituted alkyl group having a carbon number of 6 or less has even higher sensitivity.

In the presently disclosed negative photosensitive resin composition, the sensitizer is preferably a compound having an absorption coefficient of 0.5 L/g·cm or more at a wavelength of 405 nm. A resin film obtained using a negative photosensitive resin composition containing a sensitizer that has an absorption coefficient of 0.5 L/g·cm or more at a wavelength of 405 nm has even higher sensitivity.

The “absorption coefficient (L/g·cm) at a wavelength of 405 nm” referred to in the present description can be measured in accordance with JIS K 0115.

In the presently disclosed negative photosensitive resin composition, it is preferable that the alkali-soluble resin includes a cycloolefin monomer unit and the non-ionic photoacid generator is contained in a proportion of 10 parts by mass or less per 100 parts by mass of the alkali-soluble resin. When the content of the non-ionic photoacid generator in the negative photosensitive resin composition is not more than the upper limit set forth above, the sensitivity of an obtained resin film can be increased while also inhibiting precipitation of the non-ionic photoacid generator at the surface of the resin film and roughening of the resin film surface.

Moreover, it is preferable that the presently disclosed negative photosensitive resin composition further comprises a crosslinking agent and that the crosslinking agent includes at least one polyfunctional epoxy compound and at least one epoxy compound having a functionality of 2 or less. By using an epoxy compound such as an epoxy resin having a functionality of 2 or less and a polyfunctional epoxy compound having a functionality of 3 or more in combination as the crosslinking agent used in the negative photosensitive resin composition, heat resistance of an obtained resin film can be suitably improved.

### Advantageous Effect

According to the present disclosure, it is possible to provide a photosensitive resin composition that has excellent storage stability and can form a resin film having sufficiently high sensitivity.

### DETAILED DESCRIPTION

The following provides a detailed description of embodiments of the present disclosure.

The presently disclosed negative photosensitive resin composition can be used to form a resin film that can be included in an electronic component such as an integrated circuit element or an organic EL element, or the like, without any specific limitations. In particular, the presently disclosed negative photosensitive resin composition is particularly suitable for use in production of an insulating organic film for organic EL or the like. Examples of active energy rays that may be used in patterning of a resin film formed using the presently disclosed negative photosensitive resin composition include, but are not specifically limited to, light rays such as ultraviolet rays, light rays of a single wavelength (for example, g-line, h-line, or i-line light rays), KrF excimer laser light, and ArF excimer laser light, and particle beams such as electron beams. The presently disclosed negative photosensitive resin composition is particularly suitable for use in a wavelength range of 300 nm to 500 nm, for example, for among the examples listed above.

(Negative Photosensitive Resin Composition)

A feature of the presently disclosed negative photosensitive resin composition is that the composition contains an alkali-soluble resin, a non-ionic photoacid generator, and a sensitizer. Through inclusion of the non-ionic photoacid generator and the sensitizer in the negative photosensitive resin composition, both sensitivity of an obtained resin film and storage stability of the photosensitive resin composition can be increased.

<Alkali-Soluble Resin>

Alkali-soluble resins that can typically be used in resist formation may be used as the alkali-soluble resin contained in the presently disclosed negative photosensitive resin composition without any specific limitations. As previously mentioned, the term “alkali-soluble resin” as used in the present description refers to “a resin that is soluble in a developer used in development of a negative photosensitive resin composition containing the resin as a component, and particularly preferably in an alkaline developer”. More specifically, “soluble in an alkaline developer” means that when an alkaline developer and a resin solution are mixed, a mixed solution that appears transparent to the naked eye is obtained. Examples of alkali-soluble resins that may be used include, but are not specifically limited to, novolac resins, polyvinyl alcohol resins, acrylic resins, polyimide resins, polybenzoxazole resins, and cycloolefin resins (i.e., resins including cycloolefin monomer units). One of these alkali-soluble resins may be used individually, or two or more of these alkali-soluble resins may be used as a mixture. The phrase “includes a monomer unit” as used with regard to a resin or polymer in the present description means that “a structural unit derived from this monomer is included in the resin or polymer obtained using the monomer”.

The alkali-soluble resin is preferably an acidic group-containing polymer or copolymer. Examples of such acidic groups include a carboxyl group, a hydroxy group, and a phenolic hydroxy group. Moreover, the alkali-soluble resin preferably includes a cycloolefin monomer unit. The phrase “includes a cycloolefin monomer unit” as used in the present description means that at least part of a constituent polymer of the alkali-soluble resin is formed by cycloolefin monomer units. More specifically, when all constituent monomer units of the polymer are taken to be 100 mass %, cycloolefin monomer units preferably constitute 10 mass % or more, more preferably 50 mass % or more, and even more preferably 80 mass % or more. Furthermore, the alkali-soluble resin is preferably a polymer or copolymer that is formed using an acidic group-containing cycloolefin monomer (hereinafter, also referred to as an “acidic group-containing cycloolefin polymer”). The alkali-soluble resin that is an acidic group-containing cycloolefin polymer may be a copolymer of an acidic group-containing cycloolefin monomer and one or more monomers that are copolymerizable with the acidic group-containing cycloolefin monomer. Examples of monomers that are copolymerizable with an acidic group-containing cycloolefin monomer include, but are not specifically limited to, a cycloolefin monomer including a polar group other than an acidic group, a cycloolefin monomer that does not include a polar group, and a monomer other than a cycloolefin.

Various monomers described in WO 2015/033901 A1, for example, can be used as the “acidic group-containing cycloolefin monomer”, the “cycloolefin monomer including a polar group other than an acidic group”, the “cycloolefin monomer that does not include a polar group”, and the “monomer other than a cycloolefin”. Each of these various monomers may be one type used individually or two or more types used as a mixture.

Examples of the “acidic group-containing cycloolefin monomer” include carboxyl group-containing cycloolefin monomers such as 2-hydroxycarbonylbicyclo[2.2.1]hept-5-ene and 4-hydroxycarbonyltetracyclo[6.2.1.1^{3,6}.0^{2,7}]dodec-9-ene (TCDC); and hydroxy group-containing cycloolefin monomers such as 2-(4-hydroxyphenyl)bicyclo[2.2.1]hept-5-ene and 4-hydroxytetracyclo[6.2.1.1^{3,6}.0^{2,7}]dodec-9-ene. Carboxyl group-containing cycloolefin monomers are preferable as the “acidic group-containing cycloolefin monomer”, with 4-hydroxycarbonyltetracyclo[6.2.1.1^{3,6}.0^{2,7}]dodec-9-ene (TCDC) being particularly preferable. When the “acidic group-containing cycloolefin monomer” includes a carboxyl group, close adherence between an obtained resin film and a target member for which the resin film is adopted can be increased. Moreover, when the “acidic group-containing cycloolefin monomer” includes a carboxyl group, reactivity with other components contained in the negative photosensitive resin composition (for example, an epoxy group-containing compound) increases, and heat resistance and the like of an obtained resin film can be improved.

Examples of the “cycloolefin monomer including a polar group other than an acidic group” include cycloolefin monomers that include an N-substituted imide group, an ester group, a cyano group, an acid anhydride group, or a halogen atom, but do not include an acidic group. Of such monomers, N-substituted imide group-containing cycloolefin monomers are preferable. Examples of N-substituted imide group-containing cycloolefin monomers include cycloolefin monomers that can, for example, be represented by the following general formula (A) or (B).

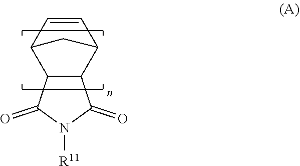

[In formula (A), R¹¹ represents a hydrogen atom or an alkyl group or aryl group having a carbon number of 1 to 16, and n represents an integer of 1 to 2.]

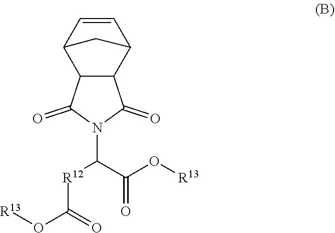

[In formula (B), R¹² represents a divalent alkylene group having a carbon number of 1 to 3, and R^{H} represents a monovalent alkyl group having a carbon number of 1 to 10 or a monovalent haloalkyl group having a carbon number of 1 to 10.]

In general formula (A), R¹¹ is an alkyl group or aryl group having a carbon number of 1 to 16. Specific examples of the alkyl group include linear alkyl groups such as a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, and an n-hexadecyl group; cyclic alkyl groups such as a cyclopropyl group, a cyclobutyl group, a cyclopentyl group, a cyclohexyl group, a cycloheptyl group, a cyclooctyl group, a cyclononyl group, a cyclodecyl group, a cycloundecyl group, a cyclododecyl group, a norbornyl group, a bornyl group, an isobornyl group, a decahydronaphthyl group, a tricyclodecanyl group, and an adamantyl group; and branched alkyl groups such as a 2-propyl group, a 2-butyl group, a 2-methyl-1-propyl group, a 2-methyl-2-propyl group, a 1-methylbutyl group, a 2-methylbutyl group, a 1-methylpentyl group, a 1-ethylbutyl group, a 2-methylhexyl group, a 2-ethylhexyl group, a 4-methylheptyl group, a 1-methylnonyl group, a 1-methyltridecyl group, and a 1-methyltetradecyl group. Specific examples of the aryl group include a benzyl group. Of these examples, alkyl groups and aryl groups having a carbon number of 6 to 14 are preferable, and alkyl groups and aryl groups having a carbon number of 6 to 10 are more preferable because this provides better heat resistance and solubility in polar solvents. A carbon number of 4 or less results in poorer solubility in polar solvents, whereas a carbon number of 17 or more results in poorer heat resistance and, in a situation in which a resin film is patterned, may also cause problems of melting due to heat and pattern loss.

Specific examples of monomers represented by general formula (A) include bicyclo[2.2.1]hept-5-ene-2,3-dicarboxyimide, N-phenylbicyclo[2.2.1]hept-5-ene-2,3-dicarboxyimide, N-methylbicyclo[2.2.1]hept-5-ene-2,3-dicarboxyimide, N-ethylbicyclo[2.2.1]hept-5-ene-2,3-dicarboxyimide, N-propylbicyclo[2.2.1]hept-5-ene-2,3-dicarboxyimide, N-butylbicyclo[2.2.1]hept-5-ene-2,3-dicarboxyimide, N-cyclohexylbicyclo[2.2.1]hept-5-ene-2,3-dicarboxyimide, N-adamantylbicyclo[2.2.1]hept-5-ene-2,3-dicarboxyimide, N-(1-methylbutyl)-bicyclo[2.2.1]hept-5-ene-2,3-dicarboxyimide, N-(2-methylbutyl)-bicyclo[2.2.1]hept-5-ene-2,3-dicarboxyimide, N-(1-methylpentyl)-bicyclo[2.2.1]hept-5-ene-2,3-dicarboxyimide, N-(2-methylpentyl)-bicyclo[2.2.1]hept-5-ene-2,3-dicarboxyimide, N-(1-ethylbutyl)-bicyclo[2.2.1]hept-5-ene-2,3-dicarboxyimide, N-(2-ethylbutyl)-bicyclo[2.2.1]hept-5-ene-2,3-dicarboxyimide, N-(1-methylhexyl)-bicyclo[2.2.1]hept-5-ene-2,3-dicarboxyimide, N-(2-methylhexyl)-bicyclo[2.2.1]hept-5-ene-2,3-dicarboxyimide, N-(3-methylhexyl)-bicyclo[2.2.1]hept-5-ene-2,3-dicarboxyimide, N-(1-butylpentyl)-bicyclo[2.2.1]hept-5-ene-2,3-dicarboxyimide, N-(2-butylpentyl)-bicyclo[2.2.1]hept-5-ene-2,3-dicarboxyimide, N-(1-methylheptyl)-bicyclo[2.2.1]hept-5-ene-2,3-dicarboxyimide, N-(2-methylheptyl)-bicyclo[2.2.1]hept-5-ene-2,3-dicarboxyimide, N-(3-methylheptyl)-bicyclo[2.2.1]hept-5-ene-2,3-dicarboxyimide, N-(4-methylheptyl)-bicyclo[2.2.1]hept-5-ene-2,3-dicarboxyimide, N-(1-ethylhexyl)-bicyclo[2.2.1]hept-5-ene-2,3-dicarboxyimide, N-(2-ethylhexyl)-bicyclo[2.2.1]hept-5-ene-2,3-dicarboxyimide (NEHI), N-(3-ethylhexyl)-bicyclo[2.2.1]hept-5-ene-2,3-dicarboxyimide, N-(1-propylpentyl)-bicyclo[2.2.1]hept-5-ene-2,3-dicarboxyimide, N-(2-propylpentyl)-bicyclo[2.2.1]hept-5-ene-2,3-dicarboxyimide, N-(1-methyloctyl)-bicyclo[2.2.1]hept-5-ene-2,3-dicarboxyimide, N-(2-methyloctyl)-bicyclo[2.2.1]hept-5-ene-2,3-dicarboxyimide, N-(3-methyloctyl)-bicyclo[2.2.1]hept-5-ene-2,3-dicarboxyimide, N-(4-methyloctyl)-bicyclo[2.2.1]hept-5-ene-2,3-dicarboxyimide, N-(1-ethylheptyl)-bicyclo[2.2.1]hept-5-ene-2,3-dicarboxyimide, N-(2-ethylheptyl)-bicyclo[2.2.1]hept-5-ene-2,3-dicarboxyimide, N-(3-ethylheptyl)-bicyclo[2.2.1]hept-5-ene-2,3-dicarboxyimide, N-(4-ethylheptyl)-bicyclo[2.2.1]hept-5-ene-2,3-dicarboxyimide, N-(1-propylhexyl)-bicyclo[2.2.1]hept-5-ene-2,3-dicarboxyimide, N-(2-propylhexyl)-bicyclo[2.2.1]hept-5-ene-2,3-dicarboxyimide, N-(3-propylhexyl)-bicyclo[2.2.1]hept-5-ene-2,3-dicarboxyimide, N-(1-methylnonyl)-bicyclo[2.2.1]hept-5-ene-2,3-dicarboxyimide, N-(2-methylnonyl)-bicyclo[2.2.1]hept-5-ene-2,3-dicarboxyimide, N-(3-methylnonyl)-bicyclo[2.2.1]hept-5-ene-2,3-dicarboxyimide, N-(4-methylnonyl)-bicyclo[2.2.1]hept-5-ene-2,3-dicarboxyimide, N-(5-methylnonyl)-bicyclo[2.2.1]hept-5-ene-2,3-dicarboxyimide, N-(1-ethyloctyl)-bicyclo[2.2.1]hept-5-ene-2,3-dicarboxyimide, N-(2-ethyloctyl)-bicyclo[2.2.1]hept-5-ene-2,3-dicarboxyimide, N-(3-ethyloctyl)-bicyclo[2.2.1]hept-5-ene-2,3-dicarboxyimide, N-(4-ethyloctyl)-bicyclo[2.2.1]hept-5-ene-2,3-dicarboxyimide, N-(1-methyldecyl)-bicyclo[2.2.1]hept-5-ene-2,3-dicarboxyimide, N-(1-methyldodecyl)-bicyclo[2.2.1]hept-5-ene-2,3-dicarboxyimide, N-(1-methylundecyl)-bicyclo[2.2.1]hept-5-ene-2,3-dicarboxyimide, N-(1-methyldodecyl)-bicyclo[2.2.1]hept-5-ene-2,3-dicarboxyimide, N-(1-methyltridecyl)-bicyclo[2.2.1]hept-5-ene-2,3-dicarboxyimide, N-(1-methyltetradecyl)-bicyclo[2.2.1]hept-5-ene-2,3-dicarboxyimide, N-(1-methylpentadecyl)-bicyclo[2.2.1]hept-5-ene-2,3-dicarboxyimide, N-phenyltetracyclo[6.2.1.1^{3,6}.0^{2,7}]dodec-9-ene-4,5-dicarboxyimide, and N-(2,4-dimethoxyphenyl)-tetracyclo[6.2.1.1^{3,6}.0^{2,7}]dodec-9-ene-4,5-dicarboxy imide.

Of cycloolefin monomers that can be represented by formula (A), N-phenylbicyclo[2.2.1]hept-5-ene-2,3-dicarboxyimide (NBPI), N-(2-ethylhexyl)-bicyclo[2.2.1]hept-5-ene-2,3-dicarboxyimide (NEHI), and the like are more preferable, and N-phenylbicyclo[2.2.1]hept-5-ene-2,3-dicarboxyimide (NBPI) is particularly preferable.

In general formula (B), R¹² is a divalent alkylene group having a carbon number of 1 to 3. Examples of the divalent alkylene group having a carbon number of 1 to 3 include a methylene group, an ethylene group, a propylene group, and an isopropylene group. Of these alkylene groups, a methylene group and an ethylene group are preferable because they provide good polymerization activity.

R¹³ in general formula (B) is a monovalent alkyl group having a carbon number of 1 to 10 or a monovalent haloalkyl group having a carbon number of 1 to 10. Examples of the monovalent alkyl group having a carbon number of 1 to 10 include a methyl group, an ethyl group, a propyl group, an isopropyl group, a butyl group, a sec-butyl group, a tert-butyl group, a hexyl group, and a cyclohexyl group. Examples of the monovalent haloalkyl group having a carbon number of 1 to 10 include a fluoromethyl group, a chloromethyl group, a bromomethyl group, a difluoromethyl group, a dichloromethyl group, a difluoromethyl group, a trifluoromethyl group, a trichloromethyl group, a 2,2,2-trifluoroethyl group, a pentafluoroethyl group, a heptafluoropropyl group, a perfluorobutyl group, and a perfluoropentyl group. Of these examples, a methyl group or an ethyl group is preferable as R¹³ because this provides excellent solubility in polar solvents.

The monomers represented by general formulae (A) and (B) can be obtained, for example, through an imidization reaction of a corresponding amine compound and 5-norbornene-2,3-dicarboxylic anhydride, but are not specifically limited to being obtained in this manner. Moreover, the obtained monomer can be efficiently isolated by using a commonly known method to perform separation and purification of the reaction liquid obtained through the imidization reaction.

Examples of the “monomer other than a cycloolefin” include α-olefins having a carbon number of 2 to 20, non-conjugated dienes such as 1,5-hexadiene, and derivatives thereof. Of these monomers, 1,5-hexadiene is preferable.

The “acidic group-containing cycloolefin polymer” that may be used as the alkali-soluble resin can be prepared through a ring-opening polymerization reaction or an addition polymerization reaction using the various monomers set forth above. A ring-opened polymer can be produced by, for example, carrying out ring-opening metathesis polymerization with respect to an acidic group-containing cycloolefin monomer such as described above and an optionally used cycloolefin monomer including a polar group other than an acidic group and/or monomer other than a cycloolefin in the presence of a metathesis reaction catalyst such as (1,3-dimesitylimidazolin-2-ylidene)(tricyclohexylphosphine)benzylideneruthenium dichloride (for example, refer to WO 2010/110323 A1). An addition polymer can be produced by carrying out addition polymerization with respect to various monomers such as set forth above using a commonly known addition polymerization catalyst.

In a case in which a ring-opened polymer is prepared as the “acidic group-containing cycloolefin polymer”, it is preferable that a ring-opened polymer obtained through the ring-opening polymerization reaction is subjected to a hydrogenation reaction so as to obtain a hydrogenated product of the ring-opened polymer in which carbon-carbon double bonds included in the main chain of the polymer are hydrogenated. When such a hydrogenated product is used as the “acidic group-containing cycloolefin polymer”, the proportion of carbon-carbon double bonds that are hydrogenated (hydrogenation rate) is normally 50% or more, and, from a viewpoint of heat resistance, is preferably 70% or more, more preferably 90% or more, and even more preferably 95% or more. Note that the “hydrogenation rate” can be measured by nuclear magnetic resonance (NMR) spectrum analysis.

In a case in which a mixed resin of two or more resins is used as the alkali-soluble resin contained in the presently disclosed negative photosensitive resin composition, the proportion constituted by the acidic group-containing cycloolefin polymer when the entire alkali-soluble resin is taken to be 100 mass % is preferably 50 mass % or more, more preferably 80 mass % or more, and even more preferably 95 mass % or more. Moreover, it is particularly preferable that the acidic group-containing cycloolefin polymer constitutes 100 mass % of the alkali-soluble resin.

<Non-Ionic Photoacid Generator>

The non-ionic photoacid generator contained in the presently disclosed negative photosensitive resin composition may be a compound that generates an acid such as a Lewis acid or a Bronsted acid upon irradiation with light rays and that is not a salt prior to decomposition. As a result of a non-ionic photoacid generator, and not an ionic photoacid generator, being included in the photosensitive resin composition as a photoacid generator, storage stability of the negative photosensitive resin composition can be significantly improved as compared to a case in which an ionic photoacid generator is included. Moreover, corrosion of metal wiring caused by a photoacid generator in a resin film in a situation in which the resin film is formed on a member having metal wiring can also be inhibited through the inclusion of a non-ionic photoacid generator as the photoacid generator.

The non-ionic photoacid generator is preferably a compound represented by general formula (I), shown below.

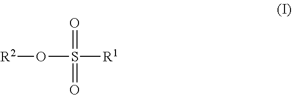

[In formula (I), R¹ indicates an optionally substituted alkyl group having a carbon number of 4 or less or an optionally substituted phenyl group, and R² indicates a nitrogen atom-containing organic group.] When the non-ionic photoacid generator is a compound that can be represented by formula (I), storage stability of the negative photosensitive resin composition can be further improved, and sensitivity of an obtained resin film can be further increased. One non-ionic photoacid generator may be used individually, or two or more non-ionic photoacid generators may be used as a mixture.

The optionally substituted alkyl group having a carbon number of 4 or less that may be indicated by R¹ in formula (I) may, for example, be an optionally substituted methyl group, ethyl group, propyl group, or butyl group. Of these groups, an optionally substituted methyl group is preferable. Examples of possible substituents of these alkyl groups having a carbon number of 4 or less include a camphor group and halogen groups such as a fluoro group and a chloro group, with a fluoro group being preferable. The optionally substituted phenyl group that may be indicated by R¹ in formula (I) may, for example, be a tolyl group (methylphenyl group), which is a phenyl group having a methyl group as a substituent, or a 4-nitrobenzene group. Of these examples, an optionally substituted alkyl group having a carbon number of 4 or less is preferable as R¹ in formula (I). Moreover, the optionally substituted alkyl group having a carbon number of 4 or less is preferably an alkyl group having at least one fluoro group as a substituent, and more preferably a trifluoromethyl group. When R¹ is a trifluoromethyl group, sensitivity of a resin film formed using the negative photosensitive resin composition can be further increased.

The nitrogen atom-containing organic group indicated by R² in formula (I) may, for example, be an organic group that includes a nitrogen atom, and that also includes an imide structure that can impart heat resistance on an obtained resin film and a light-absorbing structure or the like such as a naphthalene skeleton. R² is preferably an optionally substituted naphthalimide group, and is more preferably an unsubstituted naphthalimide group represented by formula (a), shown below. Note that “*” in formula (a) indicates a bonding site with an oxygen atom in formula (I). When R² includes a naphthalimide group, sensitivity of a resin film formed using the negative photosensitive resin composition can be further increased.

Examples of non-ionic photoacid generators including a naphthalimide group include the following products (names are indicated in parentheses) in which the various groups listed below are bonded at the “*” position in formula (a). The aforementioned groups are a trifluoromethylsulfonyloxy group (for example, NAI-105 produced by Midori Kagaku Co., Ltd.), a methylphenylsulfonyloxy group (for example, NAI-101 produced by Midori Kagaku Co., Ltd.), a methylsulfonyloxy group (for example, NAI-100 produced by Midori Kagaku Co., Ltd.), an ethylsulfonyloxy group (for example, NAI-1002 produced by Midori Kagaku Co., Ltd.), a propylsulfonyloxy group (for example, NAI-1003 produced by Midori Kagaku Co., Ltd.), a butylsulfonyloxy group (for example, NAI-1004 produced by Midori Kagaku Co., Ltd.), a nonafluorobutylsulfonyloxy group (for example, NAI-109 produced by Midori Kagaku Co., Ltd.), and a camphorsulfonyloxy group (for example, NAI-106 produced by Midori Kagaku Co., Ltd.).

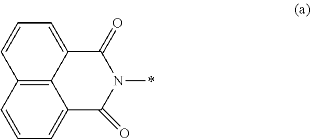 [SMILES: *N1C(=O)c2cccc3cccc(c23)C1=O]

[Content of Non-Ionic Photoacid Generator]

The content of the non-ionic photoacid generator in the negative photosensitive resin composition per 100 parts by mass of the alkali-soluble resin is preferably 10 parts by mass or less, more preferably 5 parts by mass or less, and even more preferably 4 parts by mass or less, and is preferably 1 part by mass or more, and more preferably 2 parts by mass or more. When the content of the non-ionic photoacid generator in the negative photosensitive resin composition is not more than any of the upper limits set forth above, sensitivity of an obtained resin film can be increased while also inhibiting precipitation of the non-ionic photoacid generator at the surface of the resin film and roughening of the resin film surface. On the other hand, sensitivity of an obtained resin film can be sufficiently increased when the content of the non-ionic photoacid generator in the negative photosensitive resin composition is not less than any of the lower limits set forth above.

<Sensitizer>

Any known sensitizer may be used as the sensitizer contained in the presently disclosed negative photosensitive resin composition without any specific limitations other than being a substance that can pass on received light energy to another substance. In particular, the sensitizer is preferably a sensitizer that includes an anthracene structure, and is more preferably a compound represented by general formula (II), shown below. One sensitizer may be used individually, or two or more sensitizers may be used as a mixture.

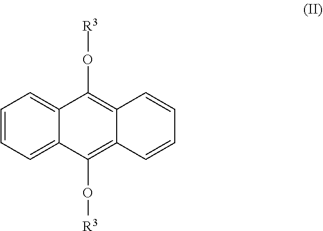

[In formula (II), R³ indicates an optionally substituted alkyl group having a carbon number of 6 or less.]

The optionally substituted alkyl group having a carbon number of 6 or less that is indicated by R³ in formula (II) is preferably a linear alkyl group. Moreover, the optionally substituted alkyl group having a carbon number of 6 or less that is indicated by R³ preferably has a carbon number of 2 or more, and more preferably has a carbon number of 3 or more. Examples of possible substituents of R³ include a carbonyl group and an alkoxy group, with a carbonyl group being preferable. R³ is preferably an unsubstituted linear alkyl group from a viewpoint of further improving sensitivity of an obtained resin film. Note that although the two R³ groups included in formula (II) may be the same as or different from one another, it is preferable that the two R³ groups are the same.

[Absorption Coefficient of Sensitizer]

The sensitizer is preferably a compound having an absorption coefficient of 0.5 L/g·cm or more at a wavelength of 405 nm. Moreover, the absorption coefficient of the sensitizer at a wavelength of 405 nm is more preferably 5 L/g·cm or more, even more preferably 10 L/g·cm or more, and further preferably 20 L/g·cm or more. When the absorption coefficient of the sensitizer at a wavelength of 405 nm is not less than any of the lower limits set forth above, sensitivity of an obtained resin film can be sufficiently increased. The absorption coefficient of the sensitizer at a wavelength of 405 nm may, for example, be 100 L/g·cm or less.

[Content of Sensitizer]

The content of the sensitizer in the negative photosensitive resin composition per 100 parts by mass of the alkali-soluble resin is preferably 2 parts by mass or more, and more preferably 4 parts by mass or more, and is preferably 10 parts by mass or less, and more preferably 8 parts by mass or less. When the content of the sensitizer in the negative photosensitive resin composition is not less than any of the lower limits set forth above, sensitivity of an obtained resin film can be sufficiently increased. On the other hand, when the content of the sensitizer in the negative photosensitive resin composition is not more than any of the upper limits set forth above, sensitivity of an obtained resin film can be increased while also inhibiting the occurrence of bleed-out, which is a phenomenon in which the sensitizer precipitates at the surface of the resin film, and roughening of the resin film surface in a situation in which a postbake is performed after development.

<Additive Components>

In addition to the various components that are described above, the presently disclosed negative photosensitive resin composition set forth above may optionally contain additive components such as a crosslinking agent, an epoxy resin, a silane coupling agent, an antioxidant, and a surfactant. Through these various additive components that may optionally be used, properties of the negative photosensitive resin composition can be further improved and/or properties that are desirable depending on the application can be imparted on the negative photosensitive resin composition.

[Crosslinking Agent]

The crosslinking agent is an agent that, through irradiation with light rays or irradiation with light rays and subsequent heat treatment, forms a crosslinked structure between crosslinking agent molecules, or that forms a crosslinked structure between resin molecules by reacting with the alkali-soluble resin or the like. Specific examples of crosslinking agents that may be used include compounds including two or more reactive groups. Examples of such reactive groups include an amino group, a carboxy group, a hydroxy group, an epoxy group, an oxetanyl group, an isocyanate group, a methylol group, and an alkoxymethyl group, with an epoxy group and a methylol group being more preferable. In other words, it is preferable to use a compound including two or more epoxy groups or a compound including two or more methylol groups as the crosslinking agent, and more preferable to use a polyfunctional epoxy compound including three or more epoxy groups or a polyfunctional methylol compound including three or more methylol groups.

Examples of epoxy group-containing compounds that may be used as the crosslinking agent include, but are not specifically limited to, epoxy resin having a bisphenol skeleton such as bisphenol A epoxy resin or bisphenol F epoxy resin, and other epoxy compounds such as phenol novolac epoxy resin, cresol novolac epoxy resin, polyphenol epoxy resin, alicyclic epoxy resin, aliphatic glycidyl ether, and epoxy acrylate polymer. One of these epoxy group-containing compounds may be used individually, or two or more of these epoxy group-containing compounds may be used as a mixture.

Of these examples, epoxy resin having a bisphenol skeleton such as bisphenol A epoxy resin or bisphenol F epoxy resin and aliphatic glycidyl ether are preferable, and epoxy resin having a bisphenol skeleton such as bisphenol A epoxy resin or bisphenol F epoxy resin is more preferable as an epoxy compound having a functionality of two or less, with bisphenol F epoxy resin being particularly preferable from a viewpoint of further increasing sensitivity of an obtained resin film.

Specific examples of polyfunctional epoxy compounds that may be used include trifunctional epoxy compounds and tetrafunctional epoxy compounds such as ε-caprolactone modified epoxidized tetrakis(3-cyclohexenylmethyl)butanetetracarboxylate (alicyclic tetrafunctional epoxy resin) disclosed in WO 2015/033901 A1.

Of these examples, the combined use of an epoxy compound such as an epoxy resin having a functionality of 2 or less and a polyfunctional epoxy compound is preferable. Through the combined use of an epoxy compound such as an epoxy resin having a functionality of 2 or less and a polyfunctional epoxy compound, heat resistance of an obtained resin film can be suitably improved while also enabling good pattern formation. Although a polyfunctional epoxy compound can impart high heat resistance on a resin film by forming a crosslinked structure with high frequency, this may cause the heat resistance of the resin film to become excessively high and the taper angle of a pattern that can be formed in the resin film to become excessively large.

The term “taper angle” refers to an angle that, when a resin film having a pattern is sectioned along a sectioning plane that is perpendicular to the resin film surface and an edge line of the pattern, is an acute angle formed between the resin film forming a pattern section and a substrate. In the present description, a surface of the resin film that is in contact with a space adjacent to the pattern section is also referred to as a “tapered surface”. The tapered surface is inclined toward an inward direction of a space section in a thickness direction of the resin film.

The taper angle is preferably 60° or less, more preferably 50° or less, and even more preferably 40° or less. In a situation in which the resin film is used as an organic insulating layer for organic EL, for example, a comparatively low taper angle of 60° or less can inhibit electrode disconnection or the like caused by a step of the organic insulating layer. This can improve the production yield of an organic EL product in which the resin film is used.

Therefore, it is preferable that the heat resistance of an obtained resin film is appropriately improved through combined use of at least one polyfunctional epoxy compound and at least one epoxy compound such as an epoxy resin having a functionality of 2 or less.

In terms of the content ratio of the polyfunctional epoxy compound and the epoxy compound having a functionality of 2 or less, the content of the polyfunctional epoxy compound is preferably 2 or more times, and more preferably 4 or more times the content of the epoxy compound having a functionality of 2 or less, and is preferably 10 or less times the content of the epoxy compound having a functionality of 2 or less from a viewpoint of achieving both an effect of improving heat resistance and an appropriate taper angle for an obtained pattern.

Furthermore, the content ratio of an epoxy compound used as the crosslinking agent in the presently disclosed negative photosensitive resin composition is preferably not less than 70 parts by mass and not more than 98 parts by mass per 100 parts by mass of the alkali-soluble resin from a viewpoint of both increasing heat resistance of an obtained resin film and enabling formation of a pattern having a good shape in the resin film. In a case in which two or more epoxy compounds such as described above are used as the epoxy compound, the total content thereof is preferably within the range set forth above.

Examples of methylol group-containing compounds that may be used as the crosslinking agent include polyfunctional methylol compounds such as 5,5′-[2,2,2-trifluoro-1-(trifluoromethyl)ethylidene]bis[2-hydroxy-1,3-benzene dimethanol] and 3,3′,5,5′-tetrakis(methoxymethyl)-1,1′-biphenyl-4,4′-diol (TMOM-BP-MF). The inclusion of a methylol compound as a crosslinking agent in the negative photosensitive resin composition can improve chemical resistance of an obtained resin film.

The content ratio of a methylol group-containing compound as the crosslinking agent in the presently disclosed negative photosensitive resin composition per 100 parts by mass of the alkali-soluble resin is preferably 10 parts by mass or less, and more preferably 8 parts by mass or less.

Examples of alkoxymethyl group-containing compounds that may be used as the crosslinking agent include compounds including an alkoxymethyl group such as a methoxymethyl group, an ethoxymethyl group, a propoxymethyl group, or a butoxymethyl group. More specific examples include polyfunctional alkoxymethyl compounds such as HMOM-TPHAP (produced by Honshu Chemical Industry Co., Ltd.) represented by general formula (γ-1), shown below; NIKALAC Mw-100LM represented by general formula (γ-2), shown below, and NIKALAC Mx-750LM represented by general formula (γ-3), shown below, which are methoxymethylated melamine compounds; NIKALAC Mx-270 represented by general formula (γ-4), shown below, which is a methoxymethyl group-containing glycoluril compound; and NIKALAC Mx-280 represented by general formula (γ-5), shown below.

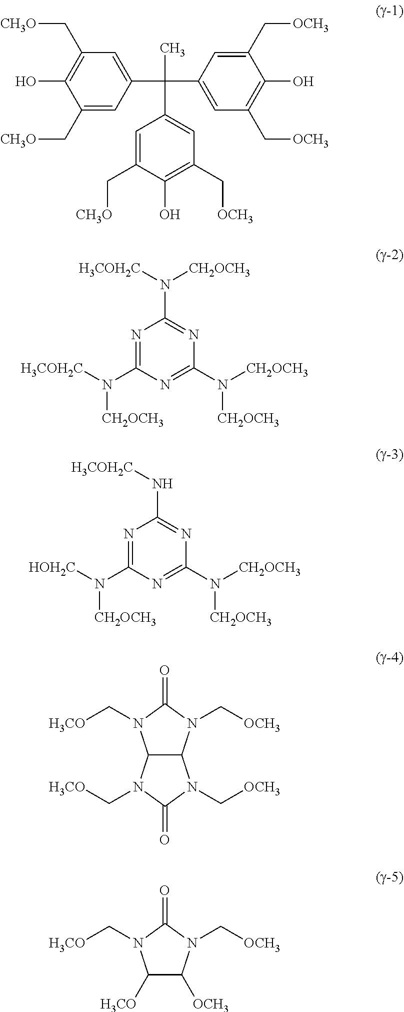

The content ratio of an alkoxymethyl group-containing compound as the crosslinking agent in the presently disclosed negative photosensitive resin composition per 100 parts by mass of the alkali-soluble resin is preferably 10 parts by mass or less, and more preferably 8 parts by mass or less.

Moreover, the content ratio of the crosslinking agent in the presently disclosed negative photosensitive resin composition is preferably not less than 70 parts by mass and not more than 100 parts by mass per 100 parts by mass of the alkali-soluble resin. In a case in which two or more compounds such as described above are used as the crosslinking agent, the total content of these compounds is preferably within the range set forth above.

[Silane Coupling Agent]

The silane coupling agent has a function of increasing close adherence between a resin film obtained using the presently disclosed negative photosensitive resin composition and a member for which the resin film is adopted. Commonly known silane coupling agents (for example, refer to JP 2015-94910 A) may be used as the silane coupling agent without any specific limitations.

[Antioxidant]

The antioxidant can improve light resistance and heat resistance of a resin film obtained using the presently disclosed negative photosensitive resin composition. Commonly known phenolic antioxidants, phosphoric antioxidants, sulfuric antioxidants, amine antioxidants, lactone antioxidants, and the like (for example, refer to WO 2015/033901 A1) may be used as the antioxidant without any specific limitations.

[Surfactant]

The surfactant can improve coatability in formation of a resin film using the presently disclosed negative photosensitive resin composition. Commonly known silicone surfactants, fluorine-containing surfactants, polyoxyalkylene surfactants, methacrylic acid copolymer surfactants, acrylic acid copolymer surfactants, and the like (for example, refer to WO 2015/033901 A1) may be used as the surfactant without any specific limitations.

<Solvent>

The presently disclosed negative photosensitive resin composition may contain a solvent. Solvents that are commonly known as solvents for resin compositions may be used as the solvent without any specific limitations. Examples of such solvents include linear ketones, alcohols, alcohol ethers, esters, cellosolve esters, propylene glycols, diethylene glycols such as diethylene glycol ethyl methyl ether, saturated γ-lactones, halogenated hydrocarbons, aromatic hydrocarbons, and polar solvents such as dimethylacetamide, dimethylformamide, and N-methylacetamide (for example, refer to WO 2015/033901 A1). These solvents may be used individually or as a combination of two or more types. The content of the solvent per 100 parts by mass of the alkali-soluble resin is preferably 10 parts by mass or more, and more preferably 50 parts by mass or more, and is preferably 10,000 parts by mass or less, more preferably 5,000 parts by mass or less, and even more preferably 1,000 parts by mass or less. In a case in which the negative photosensitive resin composition contains a solvent, the solvent is normally removed from an applied film after resin film formation.

<Production Method of Negative Photosensitive Resin Composition>

The presently disclosed negative photosensitive resin composition can be produced by mixing the essential components and the various optional components set forth above by a known method. The presently disclosed negative photosensitive resin composition may, for example, be used in the form of a negative photosensitive resin composition that is obtained when the components are dissolved in a solvent and then subjected to filtration. A known mixer such as a stirrer, a ball mill, a sand mill, a bead mill, a pigment disperser, a grinding machine, an ultrasonic disperser, a homogenizer, a planetary mixer, or a FILMIX may be used when dissolving the components in the solvent. Moreover, a typical filtration method using a filter medium such as a filter may be adopted in the filtration.

<Production Method of Resin Film>

The presently disclosed negative photosensitive resin composition can be used to form a resin film by a known film formation method (for example, refer to WO 2015/033901 A1). Moreover, the obtained resin film may, without any specific limitations, be subjected to a photoexposure step of irradiation with any active energy rays (for example, photoexposure light having a wavelength of not less than 300 nm and not more than 500 nm) and a development step so as to form a resin film having a desired pattern. Moreover, a prebake step may be implemented before the photoexposure step or a post-exposure bake (PEB) step may be implemented at a desired timing after starting the photoexposure step as necessary. Furthermore, a postbake step may be implemented after the end of the development step as necessary. The presently disclosed negative photosensitive resin composition can suitably be used even in a situation in which a postbake (main cure) step for crosslinking reaction is implemented at a low temperature of 110° C. to 130° C.

### EXAMPLES

The following provides a more specific description of the present disclosure based on examples. However, the present disclosure is not limited to the following examples. In the following description, “%” and “parts” used in expressing quantities are by mass, unless otherwise specified.

In the examples and comparative examples, the following methods were used to measure or evaluate the storage stability of a negative photosensitive resin composition, and the sensitivity, light transmittance, chemical resistance, surface roughness, and taper angle of an obtained resin film.

<Storage Stability>

A negative photosensitive resin composition produced in each example or comparative example was sealed in a light-shielding bottle and was stored in a clean room (temperature: 23° C.; humidity: 45%) for 1 week. After 1 week, the negative photosensitive resin composition that had been stored under the aforementioned conditions for 1 week was applied onto a silicon wafer substrate by spin coating to obtain an applied film under the same conditions as conditions under which a resin film of 1.5 μm in thickness can be formed using the negative photosensitive resin composition straight after production. The obtained film was heated and dried at 80° C. for 2 minutes (i.e., prebaked) using a hot plate so as to obtain a laminate comprising a resin film and a silicon wafer substrate. The film thickness of the obtained laminate was measured using a light interference-type film thickness meter (Lambda Ace produced by Dainippon Screen Mfg. Co., Ltd.). The measured film thickness X (μm) was divided by 1.5 and multiplied by 100 to calculate a resin film thickness change rate (%), which was then evaluated by the following standard.

A: Resin film thickness change rate of not less than 95(%) and not more than 105(%)

B: Resin film thickness change rate of less than 95(%) or more than 105(%)

<Sensitivity>

A negative photosensitive resin composition produced in each example or comparative example was applied onto a silicon wafer substrate by spin coating to form an applied film without the composition being stored as described above. The obtained film was heated and dried at 80° C. for 2 minutes (i.e., prebaked) using a hot plate to form a resin film of 1.5 μm in thickness. Next, in order to perform patterning of the resin film, a photoexposure step was carried out using a mask capable of forming a 10 line and space pattern and a photoexposure device (PLA501F produced by Canon Inc.) by setting a photoexposure wavelength of 300 nm to 500 nm and setting a plurality of photoexposure regions in the longitudinal direction of the line and space pattern of the mask that had differing doses from 15 mJ/cm² to 60 mJ/cm² in increments of 15 mJ/cm². Thereafter, heating (i.e., a post-exposure bake (PEB)) was performed at 120° C. for 1 minute using a hot plate, and then development was performed at 25° C. for 60 seconds using a 2.38 mass % tetramethylammonium hydroxide aqueous solution. The resin film that had been developed was rinsed for 20 seconds using ultrapure water to obtain a resin film having a line and space pattern formed from a plurality of photoexposed regions differing in terms of dose. Note that the obtained resin film was disposed on the silicon wafer substrate in the form of a laminate with the silicon wafer.

A section of the obtained laminate where lines and spaces had been formed was observed using an optical microscope. The line and space width of the resin film was measured for the regions that had been exposed to the various doses. An approximation cure was prepared from the relationship between each dose and the resin film line and space width formed under that dose. The dose at which the lines and spaces were 10 μm was calculated, and this dose was taken to be the photoexposure sensitivity. When the dose at which the lines and spaces are 10 μm is lower, this means that a pattern can be formed with lower energy or in a shorter time.

<Light Transmittance>

A negative photosensitive resin composition produced in each example or comparative example was applied onto a glass substrate (produced by Corning Incorporated; product name: Corning 1737) by spin coating and was then heated and dried at 80° C. for 2 minutes (i.e., prebaked) using a hot plate to form a resin film of 1.5 μm in thickness. Next, the resin film was subjected to a photoexposure step using a photoexposure device (PLA501F produced by Canon Inc.) with a photoexposure wavelength of 300 nm to 500 nm and a dose of 100 mJ/cm². Thereafter, heating (post-exposure bake (PEB)) was performed at 120° C. for 1 minute using a hot plate. The obtained resin film was developed at 25° C. for 60 seconds using 2.38 mass % tetramethylammonium hydroxide aqueous solution (development). The resin film that had been developed was rinsed for 20 seconds with ultrapure water (rinsing). Next, heating was performed at 230° C. in an air atmosphere for 60 minutes using an oven. In other words, a postbake was performed in an oxidizing atmosphere to obtain a laminate comprising a resin film and a glass substrate.

The obtained laminate was measured at wavelengths from 400 nm to 800 nm using a spectrophotometer V-560 (produced by JASCO Corporation). The arithmetic average light transmittance (%) from 400 nm to 800 nm was calculated from the measurement results. Note that the light transmittance of the resin film was calculated as a value corresponding to a case in which the resin film thickness is 1.5 μm using a glass substrate without an attached resin film as a blank.

It was confirmed that the resin films obtained in all of the examples and comparative examples had high light transmittance and excellent transparency after heat treatment (i.e., heat-resistant transparency).

<Chemical Resistance>

A laminate comprising a resin film and a silicon wafer substrate was obtained in the same way as in evaluation of light transmittance with the exception that a silicon wafer substrate was used as a substrate. The obtained laminate was immersed for 5 minutes in 200 mL of a resist stripper ST106 (MEA (monoethanolamine)/DMSO (dimethyl sulfoxide) mixed in 7:3 ratio) that was maintained at 25° C. in a thermostatic tank. The thickness of the resin film before and after immersion was measured using a light interference-type film thickness meter (Lambda Ace produced by Dainippon Screen Mfg. Co., Ltd.). The film thickness (μm) measured before immersion was divided by the film thickness (μm) after immersion and multiplied by 100 to calculate a resin film thickness change rate (%). It was confirmed for the resin films obtained in all of the examples and comparative examples that the rate of change in resin film thickness between before and after immersion was not less than 95(%) and not more than 105(%), and thus chemical resistance was good (A).

<Surface Roughness>

A laminate comprising a resin film and a silicon wafer substrate was obtained in the same way as in evaluation of chemical resistance. The surface of the obtained laminate was observed using a Digital Hiscope (KH-3000VD produced by HIROX Co., Ltd.), and surface roughness of the laminate was evaluated in accordance with the following standard. Note that “roughness” is identified as a region having significantly different luminance to a surrounding region.

A: No sites of roughness observed at laminate surface

B: One or more sites of roughness observed at laminate surface

<Taper Angle>

A resin film was formed in the same way as in evaluation of chemical resistance. Next, in order to perform patterning of the resin film, a mask capable of forming a 10 μm line and space pattern was used to carry out a photoexposure step with a dose corresponding to the photoexposure sensitivity measured by the previously described method. Thereafter, prebaking, development, rinsing, and postbaking were carried out in the same way as in evaluation of light transmittance to obtain a laminate comprising a resin film having a 10 μm line and space pattern and a silicon wafer substrate. An SEM micrograph of the obtained laminate was taken and the cross-sectional shape of a sectioning plane that, relative to the longitudinal direction of the line and space pattern, was a perpendicular direction (i.e., a width direction). The taper angle of the line and space pattern (i.e., an angle of 90° or less formed between a tapered surface of the resin film and the substrate surface) was measured.

Note that in all of the line and space patterns obtained in the examples and comparative examples, a space defined by at least two adjacent resin films forming line sections displayed a tapered shape that narrowed toward the substrate in the sectioning plane.

### Synthesis Example 1

<Preparation of Alkali-Soluble Resin>

A glass pressure-resistant reactor that had been purged with nitrogen was charged with 100 parts of a monomer mixture comprising 60 mol % of 4-hydroxycarbonyltetracyclo[6.2.1.1^{3,6}.0^{2,7}]dodec-9-ene (TCDC), which is an acidic group-containing cycloolefin monomer, and 40 mol % of N-phenylbicyclo[2.2.1]hept-5-ene-2,3-dicarboxyimide (NBPI), which is a cycloolefin monomer including a polar group other than an acidic group; 2.8 parts of 1,5-hexadiene, which is a monomer other than a cycloolefin; 0.02 parts of (1,3-dimesitylimidazolin-2-ylidene)(tricyclohexylphosphine)benzylideneruthenium dichloride (synthesized by method described in “Org. Lett., Vol. 1, p. 953, 1999”), which is a metathesis reaction catalyst; and 200 parts of diethylene glycol ethyl methyl ether, which is a solvent. These materials were reacted at 80° C. for 4 hours under stirring to yield a polymerization reaction liquid.

The polymerization reaction liquid was loaded into an autoclave and was subjected to a hydrogenation reaction for 5 hours under stirring and conditions of 150° C. and a hydrogen pressure of 4 MPa to yield a polymer solution containing a cycloolefin polymer as an alkali-soluble resin. The obtained cycloolefin polymer had a polymerization conversion rate of 99.9%, a polystyrene-equivalent weight-average molecular weight of 5,550, a number-average molecular weight of 3,630, a molecular weight distribution of 1.53, and a hydrogenation rate of 99.9%. The solid content concentration of the polymer solution of the cycloolefin polymer was 32.4 mass %.

### Example 1

A negative photosensitive resin composition was prepared by mixing and dissolving 100 parts of the cycloolefin polymer (alkali-soluble resin) obtained in Synthesis Example 1; 3 parts of naphthalimide triflate (NAI-105 produced by Midori Kagaku Co., Ltd.) as a non-ionic photoacid generator; 5 parts of 9,10-dibutoxyanthracene (UVS-1331 produced by Kawasaki Kasei Chemicals Ltd.; absorption coefficient at 405 nm in accordance with JIS K 0115: 23.5 L/g·cm) represented by formula (C), shown below, as a sensitizer; parts of ε-caprolactone modified epoxidized tetrakis(3-cyclohexenylmethyl)butanetetracarboxylate (EPOLEAD GT401 produced by Daicel Corporation) as a polyfunctional epoxy compound (crosslinking agent); 15 parts of bisphenol F liquid epoxy resin (jER YL983U produced by Mitsubishi Chemical Corporation) as an epoxy compound having a functionality of 2 or less (crosslinking agent); 5 parts of 5,5′-[2,2,2-trifluoro-1-(trifluoromethyl)ethylidene]bis[2-hydroxy-1,3-benzene dimethanol] (TML-BPAF-MF produced by Honshu Chemical Industry Co., Ltd.) as a methylol compound (crosslinking agent); 2 parts of glycidoxypropyltrimethoxysilane (OFS6040 produced by XIAMETER) as a silane coupling agent; 2 parts of pentaerythritol tetrakis[3-(3,5-di-tert-butyl-4-hydroxyphenyl)propionate] (Irganox 1010 produced by BASF Corporation) as an antioxidant; 300 ppm of an organosiloxane polymer (KP341 produced by Shin-Etsu Chemical Co., Ltd.) as a surfactant; and 100 parts of diethylene glycol ethyl methyl ether (EDM produced by TOHO Chemical Industry Co., Ltd.) as a solvent, and subsequently performing filtration using a polytetrafluoroethylene filter having a pore diameter of 0.45 μm. Storage stability of the negative photosensitive resin composition was evaluated by the previously described method. Moreover, the obtained negative photosensitive resin composition was used to form a resin film, and evaluations and measurements were performed by the previously described methods. The results are shown in Table 1.

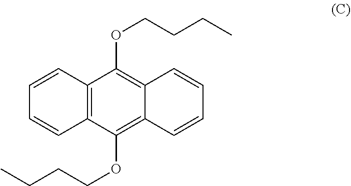 [SMILES: CCCCOc1c2ccccc2c(OCCCC)c2ccccc12]

### Example 2

A negative photosensitive resin composition and a resin film were produced in the same way as in Example 1 with the exception that the amount of naphthalimide triflate (NAI-105 produced by Midori Kagaku Co., Ltd.) used as a non-ionic photoacid generator was changed to 2 parts and the amount of bisphenol F liquid epoxy resin (jER YL983U produced by Mitsubishi Chemical Corporation) used as a crosslinking agent was changed to 10 parts. Evaluations and measurements were performed in the same way as in Example 1. The results are shown in Table 1.

### Examples 3 and 4

A negative photosensitive resin composition and a resin film were produced in the same way as in Example 1 with the exception that the amount of naphthalimide triflate (NAI-105 produced by Midori Kagaku Co., Ltd.) used as a non-ionic photoacid generator was changed to 2 parts (Example 3) or 4 parts (Example 4). Evaluations and measurements were performed in the same way as in Example 1. The results are shown in Table 1.

### Example 5

A negative photosensitive resin composition and a resin film were produced in the same way as in Example 1 with the exception that 5 parts of 9,10-diethoxyanthracene (UVS-1101 produced by Kawasaki Kasei Chemicals Ltd.; absorption coefficient at 405 nm in accordance with JIS K 0115: 35.67 L/g·cm) represented by formula (D), shown below, was used as a sensitizer. Evaluations and measurements were performed in the same way as in Example 1. The results are shown in Table 1.

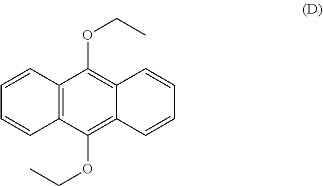 [SMILES: CCOc1c2ccccc2c(OCC)c2ccccc12]

### Example 6

A negative photosensitive resin composition and a resin film were produced in the same way as in Example 1 with the exception that 15 parts of bisphenol A liquid epoxy resin (jER YL980U produced by Mitsubishi Chemical Corporation) was used as an epoxy compound having a functionality of 2 or less (crosslinking agent). Evaluations and measurements were performed in the same way as in Example 1. The results are shown in Table 1.

### Example 7

A negative photosensitive resin composition and a resin film were produced in the same way as in Example 1 with the exception that the amount of naphthalimide triflate (NAI-105 produced by Midori Kagaku Co., Ltd.) used as a non-ionic photoacid generator was changed to 8 parts and an epoxy compound having a functionality of 2 or less (crosslinking agent) was not used. Evaluations and measurements were performed in the same way as in Example 1. The results are shown in Table 1.

### Example 8

A negative photosensitive resin composition and a resin film were produced in the same way as in Example 1 with the exception that the amount of naphthalimide triflate (NAI-105 produced by Midori Kagaku Co., Ltd.) used as a non-ionic photoacid generator was changed to 8 parts and 10 parts of a glycidyl polyetherified product of diethylene glycol (SR-2EG produced by Sakamoto Yakuhin Kogyo Co., Ltd.) was used as an epoxy compound having a functionality of 2 or less (crosslinking agent). Evaluations and measurements were performed in the same way as in Example 1. The results are shown in Table 1.

### Example 9

A negative photosensitive resin composition and a resin film were produced in the same way as in Example 1 with the exception that 5 parts of 9,10-bis(octanoyloxy)anthracene (UVS-581 produced by Kawasaki Kasei Chemicals Ltd.; absorption coefficient at 405 nm in accordance with JIS K 0115: 0.5 L/g·cm) represented by formula (E), shown below, was used as a sensitizer Evaluations and measurements were performed in the same way as in Example 1. The results are shown in Table 1.

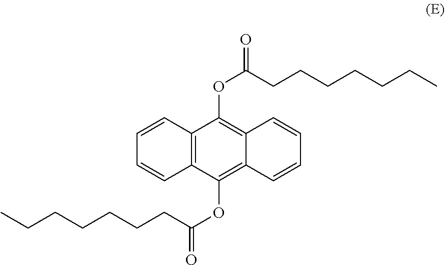 [SMILES: CCCCCCCC(=O)Oc1c2ccccc2c(OC(=O)CCCCCCC)c2ccccc12]

### Example 10

A negative photosensitive resin composition and a resin film were produced in the same way as in Example 1 with the exception that the amount of 9,10-dibutoxyanthracene (UVS-1331 produced by Kawasaki Kasei Chemicals Ltd.) used as a sensitizer was changed to 3 parts. Evaluations and measurements were performed in the same way as in Example 1. The results are shown in Table 1.

### Comparative Example 1

A negative photosensitive resin composition and a resin film were produced in the same way as in Example 1 with the exception that a sensitizer was not used. Evaluations and measurements were performed in the same way as in Example 1. The results are shown in Table 1.

### Comparative Example 2

A negative photosensitive resin composition and a resin film were produced in the same way as in Example 1 with the exception that 2 parts of 4-(phenylthio)phenyldiphenylsulfonium tris(pentafluoroethyl)trifluorophosphate (CPI-201S produced by San-Apro Ltd.), which is an ionic photoacid generator, was used instead of the non-ionic photoacid generator, and an epoxy compound having a functionality of 2 or less was not used as a crosslinking agent. Evaluations and measurements were performed in the same way as in Example 1. The results are shown in Table 1.

### Comparative Example 3

A negative photosensitive resin composition and a resin film were produced in the same way as in Example 1 with the exception that 3 parts of 4-(phenylthio)phenyldiphenylsulfonium tris(pentafluoroethyl)trifluorophosphate (CPI-201S produced by San-Apro Ltd.), which is an ionic photoacid generator, was used instead of the non-ionic photoacid generator. Evaluations and measurements were performed in the same way as in Example 1. The results are shown in Table 1.

In Table 1:

“NAI-105” indicates naphthalimide triflate (produced by Midori Kagaku Co., Ltd.);

“CPI-201S” indicates 4-(phenylthio)phenyldiphenylsulfonium tris(pentafluoroethyl)trifluorophosphate (produced by San-Apro Ltd.);

“UVS-1331” indicates 9,10-dibutoxyanthracene (produced by Kawasaki Kasei Chemicals Ltd.; formula (C));

“UVS-1101” indicates 9,10-diethoxyanthracene (produced by Kawasaki Kasei Chemicals Ltd.; formula (D));

“UVS-581” indicates 9,10-bis(octanoyloxy)anthracene (produced by Kawasaki Kasei Chemicals Ltd.; formula (E));

“GT401” indicates ε-caprolactone modified epoxidized tetrakis(3-cyclohexenylmethyl)butanetetracarboxylate (produced by Daicel Corporation);

“SR-2EG” indicates diethylene glycol diglycidyl ether (produced by Sakamoto Yakuhin Kogyo Co., Ltd.);

“jER YL-983U” indicates bisphenol F liquid epoxy resin (produced by Mitsubishi Chemical Corporation);

“jER YL-980U” indicates bisphenol A liquid epoxy resin (produced by Mitsubishi Chemical Corporation);

“TML-BPAF-MF” indicates 5,5′-[2,2,2-trifluoro-1-(trifluoromethyl)ethylidene]bis[2-hydroxy-1,3-benzene dimethanol] (produced by Honshu Chemical Industry Co., Ltd.);

“OFS6040” indicates glycidoxypropyltrimethoxysilane (produced by XIAMETER);

“Irg1010” indicates pentaerythritol tetrakis[3-(3,5-di-tert-butyl-4-hydroxyphenyl)propionate] (produced by BASF Corporation);

“KP341” indicates organosiloxane polymer (produced by Shin-Etsu Chemical Co., Ltd.); and

“EDM” indicates diethylene glycol ethyl methyl ether.

TABLE 1

| | | | | Exam- | Exam- | Exam- | Exam- | Exam- | Exam- | Exam- |
|---|---|---|---|---|---|---|---|---|---|---|
| | | | | ple 1 | ple 2 | ple 3 | ple 4 | ple 5 | ple 6 | ple 7 |
| Resin | Alkali-soluble resin | | Cycloolefin resin ┌parts┐ | 100 | 100 | 100 | 100 | 100 | 100 | 100 |
| composition | Non-ionic photoacid generator | | NAI-105 ┌parts┐ | 3 | 2 | 2 | 4 | 3 | 3 | 8 |
| | Ionic photoacid generator | | CPI-201S ┌parts┐ | — | — | — | — | — | — | — |
| | Sensitizer | Absorption coefficient: | UVS-1331 ┌parts┐ | 5 | 5 | 5 | 5 | — | 5 | 5 |
| | | 23.5 ┌L/g · cm┐ | | | | | | | | |
| | | Absorption coefficient: | UVS-1101 ┌parts┐ | — | — | — | — | 5 | — | — |
| | | 35.67 ┌L/g · cm┐ | | | | | | | | |
| | | Absorption coefficient: | UVS-581 ┌parts┐ | — | — | — | — | — | — | — |
| | | 0.5 ┌L/g · cm┐ | | | | | | | | |
| | Crosslinking | Polyfunctional | GT401 ┌parts┐ | 80 | 80 | 80 | 80 | 80 | 80 | 80 |
| | agent | epoxy compound | | | | | | | | |
| | | Epoxy compound | SR-2EG ┌parts┐ | — | — | — | — | — | — | — |
| | | having functionality | jER YL-983U ┌parts┐ | 15 | 10 | 15 | 15 | 15 | — | — |
| | | of 2 or less | jER YL-980U ┌parts┐ | — | — | — | — | — | 15 | — |
| | | Polyfunctional | TML-BPAF-MF ┌parts┐ | 5 | 5 | 5 | 5 | 5 | 5 | 5 |
| | | methylol compound | | | | | | | | |

| | | | | | | | | |
|---|---|---|---|---|---|---|---|---|
| Silane coupling agent | OFS6040 ┌parts┐ | 2 | 2 | 2 | 2 | 2 | 2 | 2 |
| Antioxidant | Irg1010 ┌parts┐ | 2 | 2 | 2 | 2 | 2 | 2 | 2 |
| Surfactant | KP341 ┌ppm┐ | 300 | 300 | 300 | 300 | 300 | 300 | 300 |
| Solvent | EDM ┌parts┐ | 100 | 100 | 100 | 100 | 100 | 100 | 100 |

| | | | | | | | | |
|---|---|---|---|---|---|---|---|---|
| Evaluation | Sensitivity ┌mJ/cm²┐ | 32 | 32 | 37 | 18 | 34 | 41 | 32 |
| | Light transmittance ┌%┐ | 99 | 99 | 99 | 96 | 96 | 98 | 96 |
| | Chemical resistance | A | A | A | A | A | A | A |
| | Surface roughness | A | A | A | A | A | A | B |
| | Taper angle ┌°┐ | 30 | 38 | 35 | 40 | 32 | 39 | 67 |
| | Storage stability | A | A | A | A | A | A | A |

| | | | | | | Compar- | Compar- | Compar- |
|---|---|---|---|---|---|---|---|---|
| | | | | | | ative | ative | ative |
| | | | Exam- | Exam- | Exam- | Exam- | Exam- | Exam- |
| | | | ple 8 | ple 9 | ple 10 | ple 1 | ple 2 | ple 3 |
| Resin | Alkali-soluble resin | Cycloolefin resin ┌parts┐ | 100 | 100 | 100 | 100 | 100 | 100 |
| composition | Non-ionic photoacid generator | NAI-105 ┌parts┐ | 8 | 3 | 3 | 3 | — | — |
| | Ionic photoacid generator | CPI-201S ┌parts┐ | — | — | — | — | 2 | 3 |

| | | | | | | | | |
|---|---|---|---|---|---|---|---|---|
| Sensitizer | Absorption coefficient: | UVS-1331 ┌parts┐ | 5 | — | 3 | — | — | 5 |
| | 23.5 ┌L/g · cm┐ | | | | | | | |
| | Absorption coefficient: | UVS-1101 ┌parts┐ | — | — | — | — | — | — |
| | 35.67 ┌L/g · cm┐ | | | | | | | |
| | Absorption coefficient: | UVS-581 ┌parts┐ | — | 5 | — | — | — | — |
| | 0.5 ┌L/g · cm┐ | | | | | | | |
| Crosslinking | Polyfunctional | GT401 ┌parts┐ | 80 | 80 | 80 | 80 | 80 | 80 |
| agent | epoxy compound | | | | | | | |
| | Epoxy compound | SR-2EG ┌parts┐ | 10 | — | — | — | — | — |
| | having functionality | jER YL-983U ┌parts┐ | — | 15 | 15 | 15 | — | 15 |
| | of 2 or less | jER YL-980U ┌parts┐ | — | — | — | — | — | — |
| | Polyfunctional | TML-BPAF-MF ┌parts┐ | 5 | 5 | 5 | 5 | 5 | 5 |
| | methylol compound | | | | | | | |

| | | | | | | | |
|---|---|---|---|---|---|---|---|
| Silane coupling agent | OFS6040 ┌parts┐ | 2 | 2 | 2 | 2 | 2 | 2 |
| Antioxidant | Irg1010 ┌parts┐ | 2 | 2 | 2 | 2 | 2 | 2 |
| Surfactant | KP341 ┌ppm┐ | 300 | 300 | 300 | 300 | 300 | 300 |
| Solvent | EDM ┌parts┐ | 100 | 100 | 100 | 100 | 100 | 100 |

| | | | | | | | |
|---|---|---|---|---|---|---|---|
| Evaluation | Sensitivity ┌mJ/cm²┐ | 27 | 63 | 43 | 65 | 18 | 16 |
| | Light transmittance ┌%┐ | 97 | 96 | 99 | 99 | 99 | 99 |
| | Chemical resistance | A | A | A | A | A | A |
| | Surface roughness | B | A | A | A | A | A |
| | Taper angle ┌°┐ | 56 | 38 | 35 | 40 | 52 | 40 |
| | Storage stability | A | A | A | A | B | B |

It can be seen from Table 1 that the negative photosensitive resin compositions of Examples 1 to 10, which each contained an alkali-soluble resin, a non-ionic photoacid generator, and a sensitizer had excellent storage stability and enabled formation of a resin film having sufficient sensitivity.

On the other hand, it can be seen that it was not possible to increase both resin composition storage stability and sensitivity of an obtained resin film with the negative photosensitive resin composition of Comparative Example 1 in which a sensitizer was not used and with the negative photosensitive resin compositions of Comparative Examples 2 and 3 in which an ionic photoacid generator was used.

### INDUSTRIAL APPLICABILITY

According to the present disclosure, it is possible to provide a photosensitive resin composition that has excellent storage stability and can form a resin film having sufficiently high sensitivity.

1. A negative photosensitive resin composition comprising an alkali-soluble resin, a non-ionic photoacid generator, and a sensitizer.

2. The negative photosensitive resin composition according to claim 1, wherein the non-ionic photoacid generator is a compound represented by general formula (I), shown below, 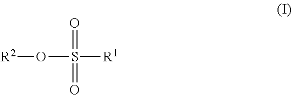
where, in general formula (I), R¹ indicates an optionally substituted alkyl group having a carbon number of 4 or less or an optionally substituted phenyl group, and R² indicates a nitrogen atom-containing organic group.

3. The negative photosensitive resin composition according to claim 2, wherein R¹ is a trifluoromethyl group.

4. The negative photosensitive resin composition according to claim 2, wherein R² is a naphthalimide group.

5. The negative photosensitive resin composition according to claim 1, wherein the sensitizer is a compound represented by general formula (II), shown below, 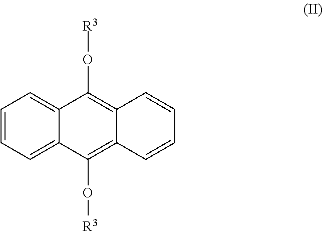
where, in general formula (II), R³ indicates an optionally substituted alkyl group having a carbon number of 6 or less.

6. The negative photosensitive resin composition according to claim 5, wherein R³ is an unsubstituted alkyl group having a carbon number of 6 or less.

7. The negative photosensitive resin composition according to claim 1, wherein the sensitizer is a compound having an absorption coefficient of 0.5 L/g·cm or more at a wavelength of 405 nm.

8. The negative photosensitive resin composition according to claim 1, wherein
the alkali-soluble resin includes a cycloolefin monomer unit, and
the non-ionic photoacid generator is contained in a proportion of 10 parts by mass or less per 100 parts by mass of the alkali-soluble resin.

9. The negative photosensitive resin composition according to claim 1, further comprising a crosslinking agent, wherein
the crosslinking agent includes at least one polyfunctional epoxy compound having a functionality of 3 or more and at least one epoxy compound having a functionality of 2 or less.
